(19) United States
(12) Patent Application Publication
(10) Pub. No.: US 2007/0051050 A1
(43) Pub. Date: Mar. 8, 2007

(54) Diamond particle for sintering tool and manufacturing method thereof and sintering tool using the same

(75) Inventor: Seung-Woo Nam, Chungcheongbuk-do (KR)

Correspondence Address: BANNER & WITCOFF, 1001 G STREET N W, SUITE 1100, WASHINGTON, DC, 20001, US

(73) Assignee: Iljin Diamond Co., Ltd., Mapo-gu (KR)

(21) Appl. No.: 10/548,808

(22) PCT Filed: Mar. 3, 2004
(86) PCT No.: PCT/KR04/00451

§ 371 Date: Oct. 24, 2006

(30) Foreign Application Priority Data
Mar. 15, 2003 (KR) 10-2003-0016262

(51) Int. Cl. B24D 3/02; C23C 16/00; B05D 3/00

(52) U.S. Cl. 51/307; 427/248.1; 427/561; 427/585

(57) ABSTRACT

A diamond particle is provided, which includes a coating layer including Cr (chromium) of about 1˜6%, Al (aluminum) of about 3˜11%, Si (silicon) of about 4˜14%, and titanium (Ti). Advantageously, surface corrosion of the diamond particle is low due to excellent anti-corrosion and anti-oxidization of the coating layer and a retention force is high when it is used for a sintering tool. Further, the sintering tool having the diamond particle has a long life span and an excellent cutting capability.

### TECHNICAL FIELD

The present invention relates to a diamond particle for a sintering tool being of small surface corrosion after sintering.

### DESCRIPTION OF THE RELATED ART

Diamond has a super hardness and a super heat conductivity so that it is widely used for cutting and grinding stone, concrete, asphalt, ceramic, and etc. Generally, the diamond is used as a sintering tool after sintering with a matrix metal (hereinafter “metal bond”) such as Co, Bronze, Cu, Ni, Fe, W, and Sn.

However, when a pure diamond particle is sintered with the metal bond, a retention force which is a force for holding the diamond particle by the metal bond is weak, and the diamond is changed to graphite by a catalysis reaction with the metal bond during sintering at a high temperature, which is generally called a regraphite reaction, thereby causing corrosion of the surface.

To solve above described problems, Ti is coated on a diamond particle and the coated diamond is sintered with a metal bond. The Ti coating layer increases a retention force of the diamond with the metal bond because a bond between the metal bond and the diamond is excellent and increases a life-span of a tool because it prevents a regraphite reaction by blocking the metal bond.

However, as the regraphite reaction is active as increasing a regraphite reaction temperature, the Ti coating layer for the metal bond having a lower sintering temperature such as Co, Bronze, and Cu has an advantage. On the contrary, the Ti coating layer for the metal bond having over 850° C. of a higher sintering temperature such as Fe and W is limited to prevent the regraphite reaction. Further, as a reactivity of Ti with the metal bond is very high at a higher temperature, the Ti can be consumed by a reaction of the Ti and the metal bond, thereby increasing a surface corrosion of the diamond.

### SUMMARY OF THE INVENTION

Therefore, it is an object of the present invention to provide a diamond particle including a coating layer for a sintering tool and a method thereof, wherein the coating layer includes a given amount of titanium (Ti) and chromium (Cr) as well as aluminum (Al) and silicon (Si) which are excellent for anti-corrosion and anti-oxidation, and wherein the coating layer is deposited on the diamond particle for protection a surface corrosion.

Further, it is another object of the present invention to provide a sintering tool by sintering the diamond particle including the coating layer with a metal bond, wherein the sintering tool has an excellent characteristic after severely sintering.

According to an embodiment of the present invention, the diamond particle for sintering tool includes: a coating layer comprising chromium (Cr) of about 1˜6%, aluminum (Al) of about 3˜11%, silicon (Si) of about 4˜14%, and titanium and impurities.

### BRIEF DESCRIPTION OF THE DRAWINGS

The above objects and other advantages of the present invention will become more apparent by describing in detail preferred embodiments thereof with reference to the attached drawings in which:

FIG. 1 is a SEM (Scanning Electron Microscope) photograph taking a surface corrosion state of a conventional diamond particle and a diamond particle according to an embodiment of the present invention after removing a coating layer;

FIG. 2 is a graph comparing a performance of a sintering tool of a conventional diamond particle and a diamond particle according to an embodiment of the present invention; and

FIG. 3 is a graph of an Auger electron microscope analysis result of a diamond particle having a coating layer according to an embodiment of the present invention.

### DETAILED DESCRIPTION OF PREFERRED EMBODIMENTS

Hereinafter, preferred embodiments of the present invention will be described in detail with reference to the accompanying drawings. It should be noted that like reference numerals are used for designation of like or equivalent parts or portion for simplicity of illustration and explanation.

The titanium (Ti) has an excellent characteristic for bonding a metal bond and diamond. Thus, it is necessary to include a coating layer for maintaining a retention force of diamond, which is required for a sintering tool. However, as the titanium (Ti) may be consumed when a sintering temperature is high, chromium (Cr) which has characteristics of anti-corrosion and anti-oxidation is further included in the coating layer.

With increasing the content of the chromium (Cr), as the coating layer having the titanium (Ti) and the chromium (Cr) may be brittle, it has a limitation to increase the content of the chromium (Cr).

Therefore, it is an object to solve above described problems by including silicon (Si) and aluminum (Al) in a titanium (Ti) and chromium (Cr) coating layer, wherein the silicon (Si) and the aluminum (Al) shows good characteristics about anti-corrosion and anti-oxidation.

A composition of the coating layer will be described according to an embodiment of the present invention.

Chromium (Cr) has a lower reactivity with a metal bond compared with titanium (Ti). However, the chromium has excellent characteristics of corrosion and oxidation resistances because the chromium forms carbide by reaction with carbon of diamond, thereby strong bonding with the diamond. Further, even if the chromium is sintered at a high temperature, it prevents a regraphite reaction. However, when an excessive amount of the chromium is added, as a bonding structure is brittle, it is preferable to include the chromium of about 1 to about 6%.

Silicon (Si) has a lower reactivity with a metal bond. However, the silicon has excellent characteristics of corrosion and oxidation resistances and has an excellent effect for preventing surface corrosion because it does not react with titanium. However, when an excessive amount of the silicon is added, as a retention force of a metal bond is deteriorated during sintering, it is preferable to include the silicon of about 4 to about 14%.

Aluminum (Al) has a lower reactivity with a metal bond compared with titanium (Ti). However, the aluminum has excellent characteristics of corrosion and oxidation resistances and has an excellent effect for preventing surface corrosion. However, for preventing deterioration of a retention force of a metal bond during sintering, it is preferable to include the aluminum of about 3 to about 11%.

A residual is titanium (Ti) which is a necessary element. When the coating layer including the titanium (Ti), the chromium (Cr), the silicon (Si), and the aluminum (Al) is coated on a diamond particle having an average particle diameter of about 10˜1000 μm, a diamond particle for a sintering tool according to an embodiment of the present invention can be obtained.

According to an embodiment of the present invention, a diamond particle for a sintering tool includes a coating layer by a heat-evaporation process of Cr, Al, Si, and Ti powder. The coating layer preferably includes about Cr of 1˜6%, Al of about 3˜11%, Si of about 4˜14%, Ti, and inevitable impurities.

The heat-evaporation process includes a chemical vapor deposition (CVD) method, a physical vapor deposition (PVD) method, and a metal vapor deposition (MVD) method. According to a preferred embodiment of the present invention, the metal vapor deposition (MVD) method is preferably used because the coating layer is formed at a relatively lower temperature.

The MVD method is to deposit metal vapor on a target surface after heat-evaporation of the metal powder under vacuum atmosphere. As the metal vapor can be deposited at a lower temperature, it has an advantage to broaden the deposition temperature.

According to an embodiment of the present invention, the heat-evaporation temperature is preferably about 750˜1000° C. For evaporation of the metal powder, a bottom temperature for the heat-evaporation is about 750° C. If the evaporation temperature exceeds about 1000° C., a regraphite reaction may occur, so that the heat-evaporation temperature is preferably about 750˜1000° C. Another advantage of an embodiment of the present invention is to lower the heat-evaporation temperature by forming a coating layer having multiple elements compared to a Ti-coating layer of a conventional method.

According to an embodiment of the present invention, the heat-evaporation pressure is preferably under about 10⁻² torr to obtain a satisfactory layer and to reduce an evaporation period.

### EXAMPLE

First, a coating layer having compositions shown in Table 1 was deposited on a diamond particle (Product No. ISD-1700, manufactured by Iljin diamond) by a MVD method. Second, a sintering tool was manufactured by sintering the diamond particle having the coating layer with a metal bond of a Fe-system having iron (Fe) of about 90% and cobalt (Co) of about 10% which was actively reacted with titanium (Ti) during sintering. A sintering condition was as following: a sintering temperature was increased to about 910° C. for 3 minutes, a sintering pressure was about 350 kg/cm², and a sintering was performed under vacuum.

Table 1 shows surface corrosion status of the diamond particle after sintering.

TABLE 1

| | | | | | | Diamond surface |
|---|---|---|---|---|---|---|
| | Composition Ratio (wt %) | | | | Coating | corrosion status |
| No. | Ti | Cr | Al | Si | (wt %) | after sintering |
| Comparative | 98 | 2 | — | — | 0.30 | Occurred |
| Example 1 | | | | | | |
| Comparative | 91 | 1 | 8 | — | 0.36 | Occurred |
| Example 2 | | | | | | |
| Comparative | 75 | 9 | 16 | — | 0.19 | Occurred |
| Example 3 | | | | | | |
| Comparative | 90 | 2 | 1 | 7 | 0.31 | Occurred |
| Example 4 | | | | | | |
| Comparative | 67 | 22 | — | 11 | 0.16 | Not occurred |
| Example 5 | | | | | | |
| Comparative | 53 | 4 | 13 | 30 | 0.05 | Not occurred |
| Example 6 | | | | | | |
| Example 1 | 79 | 4 | 7 | 10 | 0.13 | Not occurred |
| Example 2 | 73 | 6 | 9 | 12 | 0.15 | Not occurred |
| Example 3 | 79 | 4 | 8 | 9 | 0.23 | Not occurred |
| Example 4 | 83 | 2 | 11 | 4 | 0.27 | Not occurred |

As shown in Table 1, corrosion was occurred for Comparative Examples 1˜4 which were deviated from the composition ranges of embodiments of the present invention. Corrosion was not occurred for Comparative Example 5, but the coating layer can be easily broken because the content of Cr was excessively high so that it was not suitable for a diamond particle for a sintering tool. Further, corrosion was not occurred for Comparative Example 6, but a retention force of the metal bond was low because the content of Si was excessively high so that it was not suitable for a diamond particle for a sintering tool.

As shown in Examples 1˜4, the content of Ti was relatively high. Thus, a retention force was high, as well as surface corrosion was not occurred so that it was suitable for a diamond particle for a sintering tool.

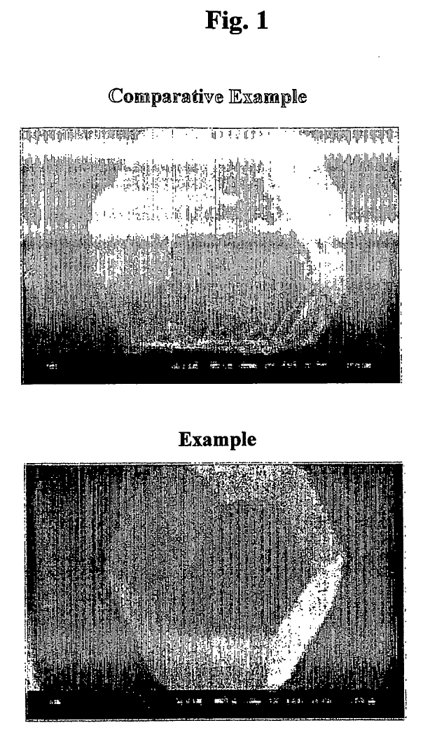

FIG. 1 is a SEM (Scanning Electron Microscope) photograph taking a surface corrosion state of diamond particles of Comparative Example 1 and Example 1 after removing a coating layer.

As shown in FIG. 1, a diamond surface which was coated with a coating layer according to an embodiment of the present invention was clean, but a diamond surface which was coated with a conventional coating layer showed some corrosion.

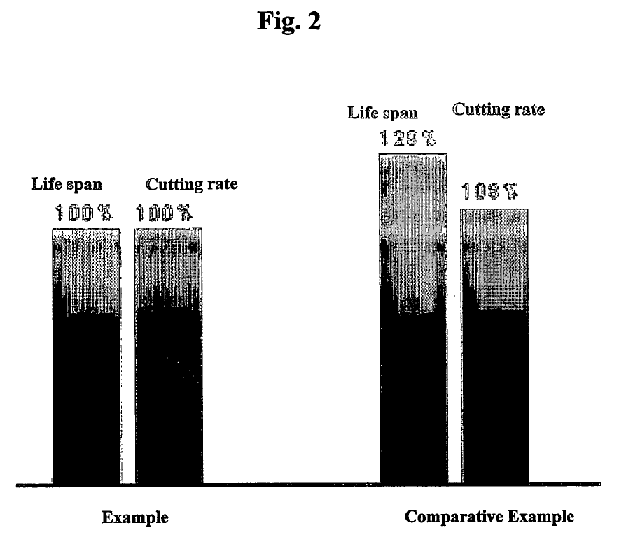

FIG. 2 is a graph comparing a performance of a sintering tool of a conventional diamond particle and a diamond particle according to an embodiment of the present invention.

First, diamond particles having compositions in Comparative Example 1 and Example 1 were respectively sintered with a metal bond having iron (Fe) of about 40%, copper (Cu) of about 25%, and tungsten (W) of about 35%. Core drills were manufactured by using the sintered particles. The core drills cut a concrete sample. After cutting the concrete sample, the tool (core drill) life span and a cutting rate were measured.

As shown in FIG. 2, a tool life span and a cutting rate of Example 1 were superior to a tool span and a cutting rate of Comparative Example 1.

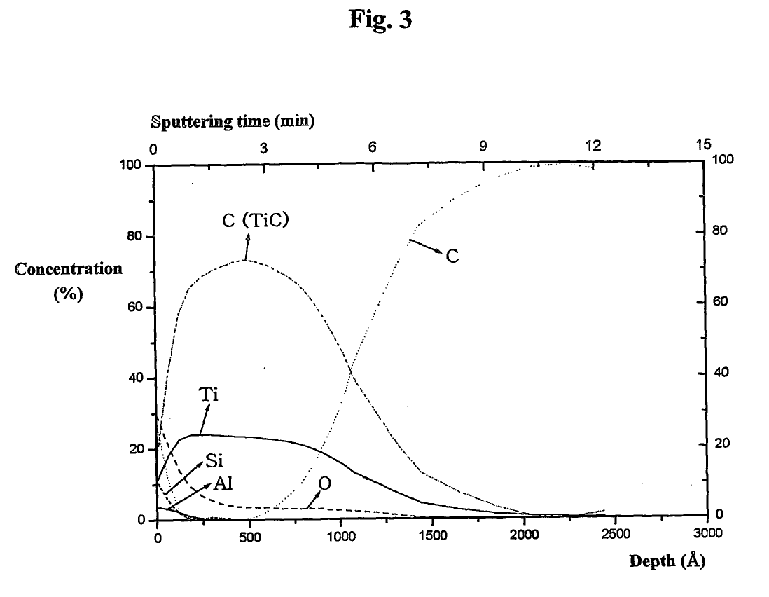

FIG. 3 is a graph of an Auger electron microscope analysis result of a diamond particle having a coating layer according to an embodiment of the present invention.

As shown in FIG. 3, silicon (Si) and aluminum (Al) appeared at an outside of the diamond particle and titanium (Ti) appeared at an inside of the diamond particle. Further, carbon appeared on the coating layer as titanium carbide. Chromium (Cr) was detected at an amount of about 2% which was analyzed by an EDX (Energy Dispersive X-ray Spectroscopy).

A forming process of the coating layer is explained in detail as below.

First, an amorphous carbon layer is formed of a diamond surface during increasing a temperature up to a coating temperature. Second, titanium vapor is attached to the amorphous carbon layer so that titanium carbide is formed. And then, small amount of chromium (Cr), aluminum (Al), silicon (Si) vapor is attached on the titanium carbide. So the coating layer is thickened. That is, the silicon (Si) and the aluminum (Al) included in the coating layer are distributed on the outer of titanium (Ti) and prohibit consuming the titanium by reaction of the metal bond so that the diamond particle is protected and the surface corrosion of the diamond particle is protected.

Advantageously, a coating layer including titanium (Ti), chromium (Cr) as well as aluminum (Al) and silicon (Si) is formed on a diamond particle so that properties of corrosion and oxidation resistances are excellent. Thus, surface corrosion is low and a retention force is high when it is used for a sintering tool.

Further, a life span and a cutting rate of the sintering tool using the diamond particle of embodiments of the present invention are excellent.

Although illustrative embodiments of the present invention have been described herein with reference to the accompanying drawings, it is to be understood that the invention is not limited to those precise embodiments, and that various other changes and modifications may be affected therein by one skilled in the art without departing from the scope or sprit of the invention.

What is claimed is:

1. A diamond particle for a sintering tool, the diamond particle comprising:
a coating layer comprising about chromium (Cr) of 1˜6%, aluminum (Al) of about 3˜11%, silicon (Si) of about 4˜14%, and titanium (Ti).

2. The diamond particle of claim 1, wherein an average diameter of the diamond particle is about 10˜1000 μm.

3. A coating method of a diamond particle for a sintering tool, the method comprising:
coating a coating layer formed of chromium (Cr), aluminum (Al), silicon (Si), and titanium (Ti) on the diamond particle by a heat-evaporation process,
wherein the coating layer comprises chromium (Cr) of about 1˜6%, aluminum (Al) of about 3˜11%, silicon (Si) of about 4˜14%, and titanium (Ti).

4. The method of claim 3, wherein a temperature for the heat-evaporation process is about 750˜1000° C.

5. The method of claim 3, wherein a pressure for the heat-evaporation process is under about 10⁻² torr.

6. A sintering tool comprising the diamond particle of claim 1.

7. A sintering tool comprising an iron (Fe)-alloy system and the diamond particle of claim 1.

8. A sintering tool comprising a tungsten(W)-alloy system and the diamond particle of claim 1.
